(19) United States
(12) Patent Application Publication
(10) Pub. No.: US 2003/0160630 A1
(43) Pub. Date: Aug. 28, 2003

(54) Bidirectional edge accelerator circuit

(76) Inventor: Adrian Earle, Kanata (CA)

Correspondence Address: BORDEN LADNER GERVAIS LLP, WORLD EXCHANGE PLAZA, 100 QUEEN STREET SUITE 1100, OTTAWA, ON, K1P 1J9, CA

(21) Appl. No.: 10/083,361

(22) Filed: Feb. 27, 2002

(51) Int. Cl. H03K 19/01

(52) U.S. Cl. 326/17

(57) ABSTRACT

A repeater circuit for detecting and accelerating the transitioning edge of a signal on a bi-directional bus. The repeater includes rising and falling edge detectors for detecting a change in the potential level of the bi-directional bus and does not require logic for determining the direction of propagation of the signal. The edge detectors subsequently activate a drive circuit for accelerating the potential level transition of the signal on the bi-directional bus. A buffer circuit can be placed between the edge detectors and the bi-directional bus to ensure that any transition on the bi-directional bus is an intended signal transition and not a voltage spike.

### FIELD OF THE INVENTION

The present invention relates to semiconductor circuits. More particularly the invention relates to bi-directional bus lines.

### BACKGROUND OF THE INVENTION

Most semiconductor devices have buses for carrying data from a source to a destination that may be far apart from each other. The buses can be uni-directional or bi-directional. An example of a uni-directional bus is an address buss that carries address data from address buffers to address decoder circuits. An example of a bi-directional bus is a data bus that carries data to and from memory sense amplifiers and data buffers. Undesirably, bus wires are often unavoidably long due to the layout of the semiconductor device. Bus wires are physically formed in a conductor material such as aluminum or copper, but still have unwanted inherent resistance and capacitance which increases with length.

It is well known that bus resistance and capacitance slows down signal propagation by loading the bus drivers. More specifically, rail to rail transitions are slow due to the inability of the bus driver to quickly overcome the resistance and capacitance of the bus line. To overcome this inherent resistance and capacitance, designers have used large bus drivers to overcome the increased load and maximise propagation speed through both uni-directional and bi-directional bus lines. FIG. 1 illustrates the typical configuration of a bi-directional bus line. A long bi-directional bus line 10 is connected to bi-directional drivers 12 and 14 at both its ends. Both bi-directional drivers 12 and 14 write data to and read data from bus line 10. Bi-directional driver 12 includes a bus driver 16 for driving input data WDATA_IN onto bus line 10 and driver 18 for driving output data RDATA_OUT from bus line 10. Bi-directional driver 14 includes a bus driver 20 for driving input data RDATA_IN onto bus line 10 and driver 22 for driving output data WDATA_OUT from bus line 10. Bus drivers 16 and 20 are large, meaning that the width to length (W/L) sizing of the transistors are large. Although bus driver sizing depends on the process and the expected load wire on the wire, a range of between 10 to 50 times the minimum feature size of the process can be used. Hence bus drivers 16 and 20 are optimally sized to overcome the resistance and capacitance of bus line 10.

Alternatively, designers have added repeater circuits at appropriate points along the long bus line to boost the signal strength and maximise propagation speed. An example of such a repeater circuit is a buffer, consisting of a pair of inverters, in series with the bus line. Hence maximum propagation speed can be obtained even if the bus drivers are not optimally sized.

The use of large bus drivers works well for large semiconductor devices such as ASIC's, DSP's and microprocessors because there is sufficient silicon area for the placement of large bus drivers. Memory devices on the other hand, are typically smaller than the previously mentioned devices and cannot afford to use large bus drivers, especially in pitch limited areas. Hence bus repeaters are required since the bus drivers are not optimally sized. Although uni-directional bus repeaters are simple and straight forward to implement, bi-directional bus repeaters that are currently in use require complex logic for determining the direction of data travel in order to activate the proper buffer. FIG. 2 illustrates the typical configuration of a bi-directional bus line with such a repeater circuit. Bi-directional drivers 12 and 14 are identical to those in FIG. 1, but are each coupled to a bus line segment 24. Both bus line segments are connected to a bi-directional repeater circuit 26 which is controlled by a control logic block 28. Within bi-directional repeater circuit 26 are two buffers 30 and 32, each having an input and output connected to both bus line segments 24. Those of skill in the art will understand that only one of buffers 30 and 32 can be turned on at any time, depending on the direction the data is travelling. The control logic block 28 includes complex logic for determining the direction of data and enabling the appropriate buffer. Unfortunately, this logic adds overhead to the design and requires significant silicon area which is unavailable.

Therefore, there is a need for a repeater circuit for long bi-directional buses that does not require complex logic and therefore does not require large amounts of silicon area to implement.

### SUMMARY OF THE INVENTION

It is an object of the present invention to obviate or mitigate at least one disadvantage of previous bi-directional bus repeater circuits. In particular, it is an object of the present invention to provide a less complex bi-directional bus repeater circuit that accelerates the transitioning edge of a signal on a bi-directional bus.

In a first aspect, the present invention provides a repeater circuit for accelerating a signal edge transition to a predetermined voltage level on a bi-directional bus. The repeater circuit includes an edge detector for detecting the signal edge transition on the bi-directional bus and providing a transition signal corresponding thereto, and a drive circuit for receiving the transition signal from the edge detector and driving the bi-directional bus to the predetermined voltage level.

An embodiment of the repeater circuit includes a buffer connected to the bi-directional bus. In an alternate aspect of the present embodiment, the buffer can include an even number of logic gates, which can be at least two inverters.

In yet another embodiment of the present invention, the edge detector includes a rising edge detector and a falling edge detector, and the drive circuit includes a first transistor and a second transistor serially connected between VDD and VSS. The first transistor has a gate coupled to the rising edge detector, the second transistor has a gate coupled to the falling edge detector, and the first and second transistors have a shared source/drain terminal connected to the bi-directional bus. In a further aspect of the present embodiment, the rising edge detector includes a NAND gate having a first input for receiving the voltage potential transition on the bi-directional bus and an output connected to the gate of the first transistor, and an inverting delay circuit for receiving the voltage potential transition on the bi-directional bus and providing an inverted voltage potential transition signal on a second input of the NAND gate. In yet another aspect of the present embodiment, the falling edge detector includes a NOR gate having a first input for receiving the voltage potential transition on the bi-directional bus and an output connected to the gate of the second transistor, and an inverting delay circuit for receiving the transition signal and providing an inverted voltage potential transition signal on a second input of the NAND gate. The inverting delay circuit can include an odd number of logic gates with capacitors and resistors to delay propagation of the transition signal.

In another aspect, the present invention provides a repeater circuit for accelerating a signal edge transition on a bi-directional bus. The repeater circuit includes a rising edge detector, a falling edge detector and a drive circuit. The rising edge detector detects a transition from a low voltage potential level to a high voltage potential level on the bi-directional bus for generating a low logic level pulse. The falling edge detector detects a transition from a high voltage potential level to a low voltage potential level on the bi-directional bus for generating a high logic level pulse. The drive circuit couples the bi-directional bus to a high voltage supply in response to the low logic level pulse and to a low voltage supply in response to the high logic level pulse.

In an alternate aspect of the present embodiment, the rising edge detector includes a NAND gate and an inverting delay circuit. The NAND gate has an input coupled to the bi-directional bus, and the inverting delay circuit has an input coupled to the bi-directional bus and an output coupled to the other input of the NAND gate.

In yet another aspect of the present embodiment, the falling edge detector includes a NOR gate and an inverting delay circuit. The NOR gate has an input coupled to the bi-directional bus, and the inverting delay circuit has an input coupled to the bi-directional bus and an output coupled to the other input of the NOR gate.

In a further aspect of the present embodiment, the drive circuit includes a p-channel transistor for coupling the high voltage supply to the bi-directional bus, and an n-channel transistor for coupling the low voltage supply to the bi-directional bus. The p-channel transistor has a gate for receiving the low logic level pulse, and the n-channel transistor has a gate for receiving the high logic level pulse.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 shows a configuration of bi-directional bus drivers of the prior art;

FIG. 2 shows a configuration of bi-directional bus drivers with a bi-directional repeater circuit of the prior art;

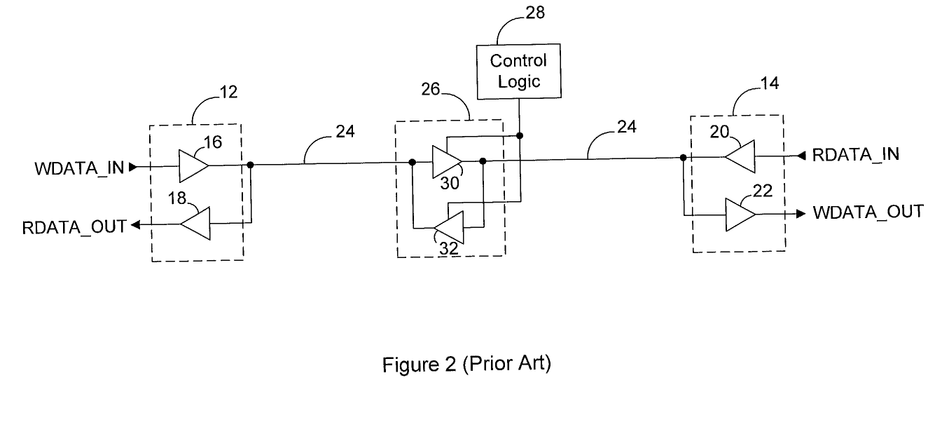

FIG. 3 shows a configuration of bi-directional bus drivers with a bi-directional repeater circuit according to an embodiment of the present invention; and,

FIG. 4 shows a circuit schematic of the bi-directional repeater circuit of FIG. 3.

### DETAILED DESCRIPTION

The present invention provides a repeater circuit for accelerating the transitioning edge of a signal on a bi-directional bus. The repeater includes rising and falling edge detectors for detecting a change in the potential level of the bi-directional bus and as a result, does not require logic for determining the direction of propagation of the signal. The edge detectors subsequently activate a drive circuit for accelerating the potential level transition of the signal on the bi-directional bus. A buffer circuit can be placed between the edge detectors and the bi-directional bus to ensure that any transition on the bi-directional bus is a true transition.

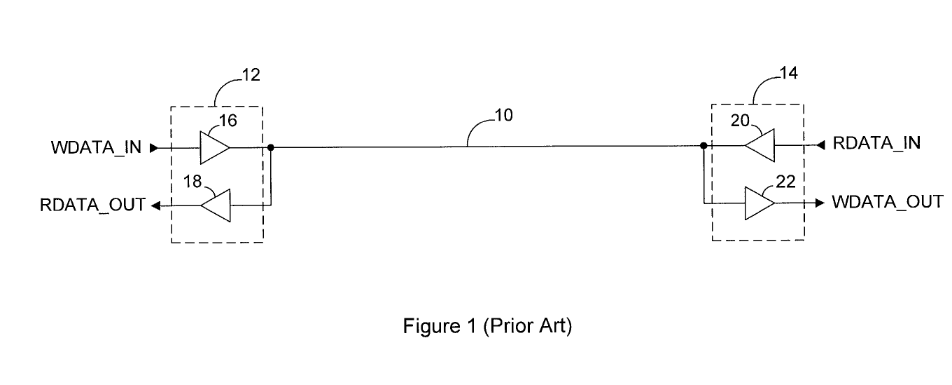

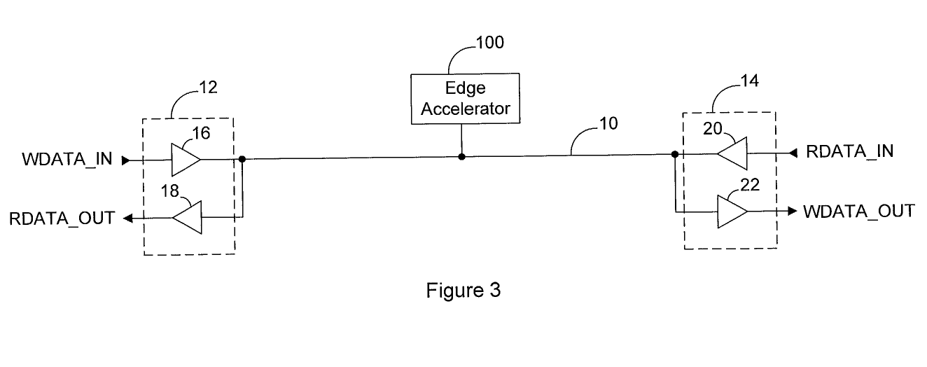

FIG. 3 is a schematic illustrating the general configuration of a bi-directional bus line with an edge accelerator circuit 100 according to an embodiment of the present invention. FIG. 3 includes all the same numbered elements of FIG. 1, and further includes edge accelerator circuit 100. The use of the edge accelerator circuit 100 permits the transistors of drivers 16 and 20 to be sized such that they can be packed into areas where silicon space is limited. Edge accelerator circuit 100 increases the speed at which a signal edge transitions from one supply voltage level to a second supply voltage level, such as ground to VDD, and does not require complex logic to determine the direction in which the signal is travelling. In the preferred embodiment of FIG. 3, edge accelerator circuit 100 is placed in parallel to and at approximately the middle of bus line 10. However, in alternate embodiments, edge accelerator circuit 100 can be placed at any point along bus line 10, and multiple edge accelerator circuits 100 can be placed along bus line 10. By placing the edge accelerator circuit 100 in parallel with drivers 16 and 20, the drive capacity of drivers 16 and 20 is augmented.

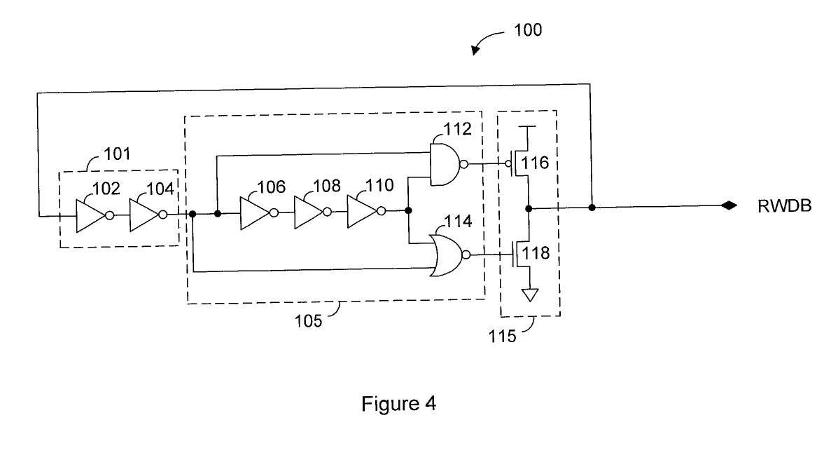

FIG. 4 is a circuit schematic of edge accelerator 100 from FIG. 3, according to an embodiment of the present invention. Edge accelerator circuit 100 is connected in parallel to a bi-directional bus line RWDB for detecting the transition of a data signal from one predetermined voltage level to another predetermined voltage level, such as from VDD to ground or from a precharged level, for example VDD/2, to a discharged level such as VSS or to a charged level such as VDD for example. It should be noted that in order to take advantage of statistical power savings properties associated with search operations in CAMs, one may choose not to precharge data bus lines to a data bus precharge voltage as is common in other commodity memory applications, and instead leave existing data from one search cycle on the data bus to be overwritten by new data in a subsequent cycle since statistically, there is a 50% chance that each data bus may remain at the same level from a previous cycle. The circuit accelerates the voltage potential transition rate of the bus line by providing additional drive current to quickly overcome the inherent resistance and capacitance of the bi-directional bus line, thus accelerating propagation of the data signal. Edge accelerator circuit 100 includes a buffer circuit 101, edge detector circuit 105, and drive circuit 115. Buffer circuit 101 receives a signal transitioning to a supply potential level (for example VDD or VSS) from bi-directional bus line RWDB, and provides a transition signal corresponding to the signal transitioning to the supply potential level to edge detector circuit 105. Edge detector circuit 105 receives the transition signal from buffer circuit 101 and generates either a logic “high” pulse signal or a logic “low” pulse signal of a fixed duration based on the number of inverters included in the edge detector circuit 105. Driver circuit 115 receives the logic “high” or logic “low” pulse signal from edge detector circuit 105 and drives bi-directional bus line RWDB to the voltage supply level. Buffer circuit 101, edge detector circuit 105 and drive circuit 115 are described in further detail below.

Buffer circuit 101 includes a pair of serially connected inverters, 102 and 104. The input of inverter 102 is connected to RWDB and its output is connected to the input of inverter 104. In this particular embodiment of the present invention, the transistor dimension ratios W/L of inverter 102 are set such that the switching point of inverter 102 is approximately VDD/2. In alternate embodiments, the switching point of inverter 102 can be set to any desired level. The main function of buffer circuit 101 is to delay the signal long enough to ensure that an actual signal transition is occurring. A voltage spike occurring on a bus line due to noise would not propagate through buffer circuit 101 because its duration is very short. Furthermore, buffer circuit 101 reduces loading of RWDB because only the two transistor gates of inverter 102 load RWDB instead of the six transistor gates of NAND gate 112, NOR gate 114 and inverter 106 which would be the case if the edge detector circuit 105 were connected directly to the data bus RWDB.

Edge detector circuit 105 includes three inverters 106, 108 and 110, a NAND gate 112 and a NOR gate 114. The input of inverter 106, a first input of NAND gate 112 and a first input of NOR gate 114 are connected in common to the output of inverter 104 of buffer circuit 101. Inverters 106, 108 and 110 are serially connected to each other as an inverter delay chain with the output of inverter 110 connected to the other input of NAND gate 112 and the other input of NOR gate 114. Inverters 106, 108 and 110, and NAND gate 112 form a rising edge detector for detecting a “low” logic level to “high” logic level transition. More specifically, the output of NAND gate 112 generates a “low” logic level pulse when the output of inverter 104 changes from the “low” to “high” logic level. Inverters 106, 108 and 110, and NOR gate 114 form a falling edge detector for detecting a “high” logic level to “low” logic level transition. More specifically, the output of NOR gate 114 generates a “high” logic level pulse when the output of inverter 104 changes from the “high” to “low” logic level. The length of the “high” or “low” logic level pulses is determined by the delay of inverters 106, 108 and 110. Resistors and MOS capacitors can be added to the outputs of inverters 106, 108 and 110 to further delay propagation of the signal from inverter 104 and increase the pulse duration from NAND gate 112 and NOR gate 114. In an alternative embodiment of the present invention, edge detector 105 can provide asymmetric delay such that the “low” logic level pulse from NAND gate 112 is longer than the “low” logic level pulse from NOR gate 114, for example. Conversely, the “high” logic level pulse from NOR gate 114 can be set to be longer than the “high” logic level pulse from NAND gate 112. Techniques for providing such asymmetric delay are well known in the art, and do not require further discussion. Alternatively, buffer circuit 101 can be omitted, and edge detector circuit 105 then detects the signal transitioning to the supply potential level from bi-directional bus line RWDB and provides a transition signal from either NAND gate 112 or NOR gate 114 to drive circuit 115. The delay circuit comprising inverters 106, 108 and 110 would then receive the voltage potential transition on the bi-directional bus for providing an inverted voltage potential transition signal to NAND gate 112 and NOR gate 114.

Drive circuit 115 includes a p-channel transistor 116 and an n-channel transistor 118 serially connected between voltage supplies VDD and ground for coupling the bi-directional bus 10 to VDD or ground. The gate of transistor 116 is connected to the output of NAND gate 112 and the gate of transistor 118 is connected to the output of NOR gate 114. The shared source/drain terminal of transistors 116 and 118 is connected to bi-directional bus line RWDB. Since edge accelerator circuit 100 can be placed in an area where there are fewer space restrictions, the sizes of transistors 116 and 118 can be made large.

The general operation of edge accelerator circuit 100 is now described with reference to FIGS. 3 and 4 in the situation where either bus driver 16 or 20 drives a “low” logic level signal onto bi-directional bus line 10. In this particular example, it is assumed that RWDB is maintained at the “high” logic level, such as VDD, from a previous access operation from RWDB. Therefore the output of inverter 104 is at the “high” logic level, the first inputs of NAND gate 112 and NOR gate 114 are at the “high” logic level, and the second inputs of NAND gate 112 and NOR gate 114 are at the “low” logic level, such as ground. Hence the output of NAND gate 112 is at the “high” logic level to keep transistor 116 turned off, and the output of NOR gate 114 is at the “low” logic level to keep transistor 118 turned off. When either bus driver 16 or 20 starts driving RWDB to ground, the potential level of RWDB drops slowly because bus drivers 16 and 20 are small. When the potential level of RWDB drops from VDD to VDD/2, inverter 102 begins to switch states, causing inverter 104 to quickly drive the first inputs of gates 112, 114 and inverter 106 to the “low” logic level. Now both inputs to NOR gate 114 are at the “low” logic level, and its output drives the gate of transistor 118 to VDD. Consequently, transistor 118 turns on to couple RWDB to VSS, assisting the bus drivers 16 or 20 and accelerating the rate at which RWDB is driven to VSS. Eventually the output of inverter 110 drives the second inputs of gates 112 and 114 to the “high” logic level, forcing NOR gate 114 to turn off transistor 118. Therefore NOR gate 114 generates a “high” logic level pulse in response to a VDD-to-VSS transition on RWDB. Conversely if RWDB was driven from VSS to VDD, then NAND gate 112 would generate a “low” logic level pulse to turn on transistor 116 for the duration of the “low” logic level pulse. Therefore, the rising or falling edge of RWDB can be accelerated towards either supply potential level of VDD or ground by edge accelerator circuit 100. This results in faster activation of drivers 18 and 22, or any circuit connected to receive RWDB.

Because edge accelerator circuit 100 is effectively in parallel with both bus drivers 16 and 20, it can boost the drive strength of a signal travelling along RWDB in both directions. As shown in FIG. 4, the circuit does not require any logic signals to determine the direction of data flow, nor does it require enabling or disabling signals. In other words, edge accelerator circuit 100 is self-activating and self-disabling. Those of skill in the art will understand that edge accelerator circuit 100 will function without buffer circuit 101. Therefore edge accelerator circuit 100 can be as few as 16 transistors and as many as 24 transistors. Even at 24 transistors, edge accelerator circuit 100 does not occupy as much silicon area as conventional repeaters and can be easily incorporated into the chip layout design. The reduction in required silicon area provides an attendant cost decrease for the chip. Simulations have shown that use of the edge accelerator circuit 100 permits the device to meet its timing requirements, where it would not if the edge accelerator circuit 100 was not used. In devices where timing requirements are already satisfied, the edge accelerator circuit 100 can be used to increase device performance.

According to an alternate embodiment of the present invention, only one half of the edge detector circuit 105 can be used. For example, a differential bus for carrying complementary signals DB and DB* precharged to the high logic level only requires one of DB and DB* to be driven to the low logic level. Therefore edge detector circuits 105 with NAND gate 112 and p-channel transistor 116 omitted, can be coupled to DB and DB* for accelerating respective falling edges. Alternatively, NOR gate 114 and n-channel transistor 118 can be omitted for accelerating rising edges.

In yet another embodiment of the present invention the rising and falling edge detectors can be separated, each having its own inverter delay chain, for placement at different positions along a bus line if there is insufficient space to form a full edge accelerator circuit 100. Furthermore, edge detector circuit 105 can be designed to provide a hysteresis or Schmidt trigger effect on its output.

The above-described embodiments of the invention are intended to be examples of the present invention. Alterations, modifications and variations may be effected the particular embodiments by those of skill in the art, without departing from the scope of the invention which is defined solely by the claims appended hereto.

What is claimed is:

1. A repeater circuit for accelerating a signal edge transition to a predetermined voltage level on a bi-directional bus comprising:
an edge detector for detecting the signal edge transition on the bi-directional bus and providing a transition signal corresponding thereto; and,
a drive circuit for receiving the transition signal from the edge detector and driving the bi-directional bus to the predetermined voltage level.

2. The repeater circuit of claim of claim 1, wherein the edge detector includes a buffer connected to the bi-directional bus.

3. The repeater circuit of claim 2, wherein the buffer includes an even number of logic gates.

4. The repeater circuit of claim 3, wherein the buffer includes at least two inverters.

5. The repeater circuit of claim 1, wherein the edge detector includes a rising edge detector and a falling edge detector.

6. The repeater circuit of claim 5, wherein the drive circuit includes
a first transistor and a second transistor serially connected between VDD and VSS,
the first transistor having a gate coupled to the rising edge detector, the second transistor having a gate coupled to the falling edge detector, and the first and second transistors having a shared source/drain terminal connected to the bi-directional bus.

7. The repeater circuit of claim 6, wherein the rising edge detector includes
a NAND gate having a first input for receiving the voltage potential transition on the bi-directional bus and an output connected to the gate of the first transistor; and,
an inverting delay circuit for receiving the voltage potential transition on the bi-directional bus and providing an inverted voltage potential transition signal on a second input of the NAND gate.

8. The repeater circuit of claim 6, wherein the falling edge detector includes
a NOR gate having a first input for receiving the voltage potential transition on the bi-directional bus and an output connected to the gate of the second transistor; and,
an inverting delay circuit for receiving the transition signal and providing an inverted voltage potential transition signal on a second input of the NAND gate.

9. The repeater circuit of claim 7 or 8, wherein the inverting delay circuit includes an odd number of logic gates.

10. The repeater circuit of claim 9, wherein the inverting delay circuit includes capacitors and resistors to delay propagation of the transition signal.

11. A repeater circuit for accelerating a signal edge transition on a bi-directional bus comprising:
(a) a rising edge detector for detecting a transition from a low voltage potential level to a high voltage potential level on the bi-directional bus and generating a low logic level pulse;
(b) a falling edge detector for detecting a transition from a high voltage potential level to a low voltage potential level on the bi-directional bus and generating a high logic level pulse; and
(c) a drive circuit for coupling the bi-directional bus to a high voltage supply in response to the low logic level pulse and to a low voltage supply in response to the high logic level pulse.

13. The repeater circuit of claim 11, wherein the rising edge detector includes a NAND gate and an inverting delay circuit, the NAND gate having an input coupled to the bi-directional bus, and the inverting delay circuit having an input coupled to the bi-directional bus and an output coupled to the other input of the NAND gate.

14. The repeater circuit of claim 11, wherein the falling edge detector includes a NOR gate and an inverting delay circuit, the NOR gate having an input coupled to the bi-directional bus, and the inverting delay circuit having an input coupled to the bi-directional bus and an output coupled to the other input of the NOR gate.

15. The repeater circuit of claim 11, wherein the drive circuit includes a p-channel transistor for coupling the high voltage supply to the bi-directional bus, an n-channel transistor for coupling the low voltage supply to the bi-directional bus, the p-channel transistor having a gate for receiving the low logic level pulse, and the n-channel transistor having a gate for receiving the high logic level pulse.
